(19) United States
(12) Patent Application Publication
(10) Pub. No.: US 2020/0064010 A1
(43) Pub. Date: Feb. 27, 2020

(54) TEMPERATURE CONTROL DEVICE, CONTROL METHOD FOR TEMPERATURE CONTROL DEVICE, AND NON-TRANSITORY STORAGE MEDIUM STORING CONTROL PROGRAM FOR TEMPERATURE CONTROL DEVICE

(71) Applicant: NEC Corporation, Tokyo (JP)

(72) Inventors: Minoru YOSHIKAWA, Tokyo (JP); Hisato SAKUMA, Tokyo (JP); Koichi TODOROKI, Tokyo (JP)

(73) Assignee: NEC Corporation, Tokyo (JP)

(21) Appl. No.: 16/494,990

(22) PCT Filed: Mar. 27, 2017
(86) PCT No.: PCT/JP2017/012383

§ 371 Date: Sep. 17, 2019

(51) Int. Cl. F24F 11/80; F24F 11/32; H05K 7/20; G06F 1/20

(52) U.S. Cl. CPC F24F 11/80; F24F 11/32; H05K 7/20836; G06F 1/206; H05K 7/20281

(57) ABSTRACT

A temperature control device comprises: first control means; and second control means. The first control means includes first cooling means for cooling of a heat carrier that moves heat from a heat source, and first adjustment means for adjusting a first cooling power being an amount of heat per time to be exchanged in the first cooling means. The second control means includes second cooling means for cooling of the heat carrier, and second adjustment means for adjusting a second cooling power being an amount of heat per time to be exchanged in the second cooling means. The second control means can compensate for a decrease in the first cooling power by a rise in the second cooling power, and can compensate for a decrease in the second cooling power by a rise in the first cooling power.

### TECHNICAL FIELD

The present invention relates to a technique for controlling a temperature of an object.

### BACKGROUND ART

Increased efficiency of air conditioning electric power needed to cool a server is required in a data center and the like. In order to reduce the air conditioning electric power, a whole air conditioning machine (a base air conditioning machine) that cools an entire server room and a local air conditioning machine that cools each server in a concentrated manner may be used together.

PTL 1 discloses one example of an air conditioning technique for using a base air conditioning machine and a local air conditioning machine together. In a heat generating source cooling system in PTL 1, a cold air area (a cold aisle) is formed on a front surface side of a server rack, and a warm air area (a hot aisle) is formed on a rear surface side of the server rack in a server room. A base air conditioning device cools the entire air in the hot aisle, and sends the air to the cold aisle. The local air conditioning machine above a specific server rack cools a part of air in the hot aisle, and sends the air to the cold aisle.

The local air conditioning machine often needs a large installation place in a server room. Thus, a small local air conditioning machine having high heat exchange capacity is required.

PTL 2 discloses one example of an air conditioning technique for achieving both of heat exchange capacity and size reduction. An air conditioning unit in PTL 2 includes one air intake chamber, and two heat exchange chambers each connected to a left side or a right side of an exit of the air intake chamber. One heat exchange coil is installed in each of the heat exchange chambers. Each of the heat exchange coils has a shape of a flat plate. Then, each of the heat exchange coils is installed obliquely in a left-and-right direction with respect to an air-blowing direction in a horizontal plane in the heat exchange chamber. Therefore, in the air conditioning unit in PTL 2, a heat exchange coil having a greater surface area can be installed, as compared to a case where a heat exchange coil is installed perpendicular to the air-blowing direction in the horizontal plane in a heat exchange chamber having a predetermined width. Then, heat exchange capacity of the heat exchange coil is higher with a greater surface area of the heat exchange coil. With the configuration above, the air conditioning unit in PTL 2 achieves both of heat exchange capacity and size reduction in a heat exchanger.

PTL 3 discloses another one example of an air conditioning technique for achieving both of heat exchange capacity and size reduction. An air conditioning device in PTL 3 includes two heat exchanging bodies. Each of the heat exchanging bodies is formed of a group of heat pipes, and has a shape of a flat plate being bent at the center in an up-and-down direction. Then, both ends of each of the heat exchanging bodies are each installed obliquely in the up-and-down direction with respect to an air-blowing direction in an installation space. Therefore, in the air conditioning device in PTL 3, a heat exchanging body having a greater surface area can be installed, as compared to a case where a heat exchanging body having a shape of a flat plate is installed perpendicular to the air-blowing direction in an installation space having a predetermined height. Then, heat exchange capacity of the heat exchanging body is higher with a greater surface area of the heat exchanging body. With the configuration above, the air conditioning device in PTL 3 achieves both of heat exchange capacity and size reduction in a heat exchanger.

A server in a data center is required to have high availability. Thus, a server in a data center often has a redundant configuration in such a way that the server can continue a service even when a part of components is faulty. A fault in a server also occurs, when the server reaches a high temperature by exceeding a predetermined limit due to a fault in a local air conditioning machine. Thus, fault tolerance in a local air conditioning machine is required to improve.

Hereinafter, it is assumed that a system for controlling (cooling or heating) a temperature of an object (a hot heat source or a cold heat source) including a local air conditioning machine is referred to as a “temperature control system”. It is also assumed that, in the temperature control system, a device that performs heat exchange by contacting an object, or a device that performs heat exchange by contacting a heat carrier that performs heat exchange by contacting an object is referred to as a “temperature control device”. On the other hand, it is assumed that, in the temperature control system, a device that performs heat exchange by contacting the temperature control device, or a device that is not an object and performs heat exchange by contacting a heat carrier that performs heat exchange by contacting the temperature control device is referred to as a “heat exhaust device”.

It is assumed that the temperature control device is referred to as a “heat receiving device” particularly in a local air conditioning machine. The heat receiving device includes a heat exchanger (an evaporator) that performs heat exchange by evaporating a liquid refrigerant and the like. Further, the heat exhaust device includes a heat exchanger (a condenser) that performs heat exchange by condensing a gas refrigerant and the like.

PTL 4 discloses one example of a technique for improving fault tolerance of a local air conditioning machine. A cooling system (a local air conditioning machine) in PTL 4 includes two heat exhaust devices (referred to as a “refrigerant device” in PTL 4), one or more heat receiving devices (referred to as a “local air conditioning machine” in PTL 4), and a control device. The heat exhaust device sends a liquid refrigerant to the heat receiving device, collects a gas refrigerant being changed from the liquid refrigerant by absorbing heat in the heat receiving device, and condenses the collected gas refrigerant by a heat exchanger (a condenser). One of the heat exhaust devices (a normal machine) operates in a normal state. The other heat exhaust device (a redundant machine) stops operating in the normal state. The heat receiving device cools a warm air by a heat exchanger (an evaporator) by using the liquid refrigerant being sent from the heat exhaust device. When the normal machine is faulty, the control device starts operating the redundant machine, and stops operating the normal machine. With the configuration above, the local air conditioning machine in PTL 4 improves fault tolerance in the heat exhaust device.

### CITATION LIST

### Patent Literature

[PTL 1] Japanese Unexamined Patent Application Publication No. 2012-193891

[PTL 2] Japanese Unexamined Patent Application Publication No. H03-137429

[PTL 3] Japanese Unexamined Patent Application Publication No. 2016-023837

[PTL 4] Japanese Unexamined Patent Application Publication No. 2013-221634

### SUMMARY OF INVENTION

### Technical Problem

However, the heat exchanger (the evaporator) included in the heat receiving device is not redundant in the cooling system in PTL 4. Further, one heat receiving device cools mainly one object. In other words, when a certain heat receiving device stops, cooling of a certain object becomes deficient. Therefore, the cooling system in PTL 4 has a problem that fault tolerance in the heat receiving device is insufficient.

The present invention has been made in view of the above-described problem, and a main object thereof is to improve fault tolerance in a temperature control device.

### Solution to Problem

In one aspect of the invention, a temperature control device includes: first heat control means including first cooling and heating means for performing either one of cooling or heating of a heat carrier that moves heat from and to a heat source, and first cooling and heating power-adjustment means for adjusting a first cooling and heating power being an amount of heat per time to be exchanged in the first cooling and heating means; and second heat control means that includes second cooling and heating means for performing either one of cooling of the heat carrier when the first cooling and heating means performs cooling of the heat carrier, or heating of the heat carrier when the first cooling and heating means performs heating of the heat carrier, and second cooling and heating power-adjustment means for adjusting a second cooling and heating power being an amount of heat per time to be exchanged in the second cooling and heating means, and that can compensate for a decrease in the first cooling and heating power by a rise in the second cooling and heating power, and can compensate for a decrease in the second cooling and heating power by a rise in the first cooling and heating power.

In one aspect of the invention, a method of controlling a temperature control device including: first heat control means including first cooling and heating means for performing either one of cooling or heating of a heat carrier that moves heat from and to a heat source, first cooling and heating power-adjustment means for adjusting a first cooling and heating power being an amount of heat per time to be exchanged in the first cooling and heating means, and first fault detection means for detecting a fault in own heat control means; and second heat control means including second cooling and heating means for performing either one of cooling of the heat carrier when the first cooling and heating means performs cooling of the heat carrier, or heating of the heat carrier when the first cooling and heating means performs heating of the heat carrier, second cooling and heating power-adjustment means for adjusting a second cooling and heating power being an amount of heat per time to be exchanged in the second cooling and heating means, and second fault detection means for detecting a fault in own heat control means, includes: when a fault in the first heat control means is not detected by the first fault detection means, and a fault in the second heat control means is not detected by the second fault detection means, setting a value at which heat from the heat source can be cooled by combining the first cooling and heating power in the first cooling and heating means being set by the first cooling and heating power-adjustment means and the second cooling and heating power in the second cooling and heating means being set by the second cooling and heating power-adjustment means; when a fault in the first heat control means is detected by the first fault detection means, increasing, by the second cooling and heating power-adjustment means, the second cooling and heating power in the second cooling and heating means to a value at which heat from the heat source can be cooled by the second heat control means alone; and when a fault in the second heat control means is detected by the second fault detection means, increasing, by the first cooling and heating power-adjustment means, the first cooling and heating power in the first cooling and heating means to a value at which heat from the heat source can be cooled by the first heat control means alone.

In one aspect of the invention, a non-temporary storage medium stores a control program for a temperature control device including: first heat control means including first cooling and heating means for performing either one of cooling or heating of a heat carrier that moves heat from and to a heat source, first cooling and heating power-adjustment means for adjusting a first cooling and heating power being an amount of heat per time to be exchanged in the first cooling and heating means, and first fault detection means for detecting a fault in own heat control means; and second heat control means including second cooling and heating means for performing either one of cooling of the heat carrier when the first cooling and heating means performs cooling of the heat carrier, or heating of the heat carrier when the first cooling and heating means performs heating of the heat carrier, second cooling and heating power-adjustment means for adjusting a second cooling and heating power being an amount of heat per time to be exchanged in the second cooling and heating means, and second fault detection means for detecting a fault in own heat control means. The control program causes a computer included in the temperature control device to execute redundancy control processing of: when a fault in the first heat control means is not detected by the first fault detection means, and a fault in the second heat control means is not detected by the second fault detection means, setting a value at which heat from the heat source can be cooled by combining the first cooling and heating power in the first cooling and heating means being set by the first cooling and heating power-adjustment means and the second cooling and heating power in the second cooling and heating means being set by the second cooling and heating power-adjustment means; when a fault in the first heat control means is detected by the first fault detection means, increasing, by the second cooling and heating power-adjustment means, the second cooling and heating power in the second cooling and heating means to a value at which heat from the heat source can be cooled by the second heat control means alone; and when a fault in the second heat control means is detected by the second fault detection means, increasing, by the first cooling and heating power-adjustment means, the first cooling and heating power in the first cooling and heating means to a value at which heat from the heat source can be cooled by the first heat control means alone.

### Advantageous Effects of Invention

The present invention has an effect capable of improving fault tolerance in a temperature control device.

### BRIEF DESCRIPTION OF DRAWINGS

FIG. 1 is a block diagram illustrating one example of a configuration of a temperature control device according to a first example embodiment of the present invention.

FIG. 2 is a front view of a temperature control device illustrating one example of a configuration of the temperature control device according to a second example embodiment of the present invention.

FIG. 3 is a perspective view of the temperature control device illustrating one example of the configuration of the temperature control device according to the second example embodiment of the present invention.

FIG. 4 is a perspective view of the temperature control device illustrating one example of the configuration of the temperature control device according to the second example embodiment of the present invention.

FIG. 5 is a cross-sectional view of the temperature control device illustrating one example of the configuration of the temperature control device in the second example embodiment of the present invention.

FIG. 6 is a cross-sectional view of the temperature control device illustrating one example of a configuration of a first modification example in the temperature control device according to the second example embodiment of the present invention.

FIG. 7 is a cross-sectional view of the temperature control device illustrating one example of a configuration of a second modification example in the temperature control device according to the second example embodiment of the present invention.

FIG. 8 is a cross-sectional view of the temperature control device illustrating one example of a configuration of a third modification example in the temperature control device according to the second example embodiment of the present invention.

FIG. 9 is an assembly view (a front view) of a temperature control device illustrating one example of a configuration of the temperature control device according to a third example embodiment of the present invention.

FIG. 10 is an assembly view (a perspective view) of the temperature control device illustrating one example of the configuration of the temperature control device according to the third example embodiment of the present invention.

FIG. 11 is an assembly view (a cross-sectional view) of the temperature control device illustrating one example of the configuration of the temperature control device according to the third example embodiment of the present invention.

FIG. 12 is a front view of a temperature control device illustrating one example of a configuration of the temperature control device according to a fourth example embodiment of the present invention.

FIG. 13 is a block diagram illustrating one example of a configuration of a temperature control device according to a fifth example embodiment of the present invention.

FIG. 14 is a flowchart illustrating an operation of the temperature control device according to the fifth example embodiment of the present invention.

FIG. 15 is a block diagram illustrating one example of a hardware configuration that can achieve the temperature control device according to each of the example embodiments of the present invention.

### EXAMPLE EMBODIMENT

Hereinafter, example embodiments of the present invention are described in detail with reference to the drawings. Note that a similar component has the same reference sign in all the drawings, and description thereof is appropriately omitted.

### First Example Embodiment

A configuration according to the present example embodiment is described.

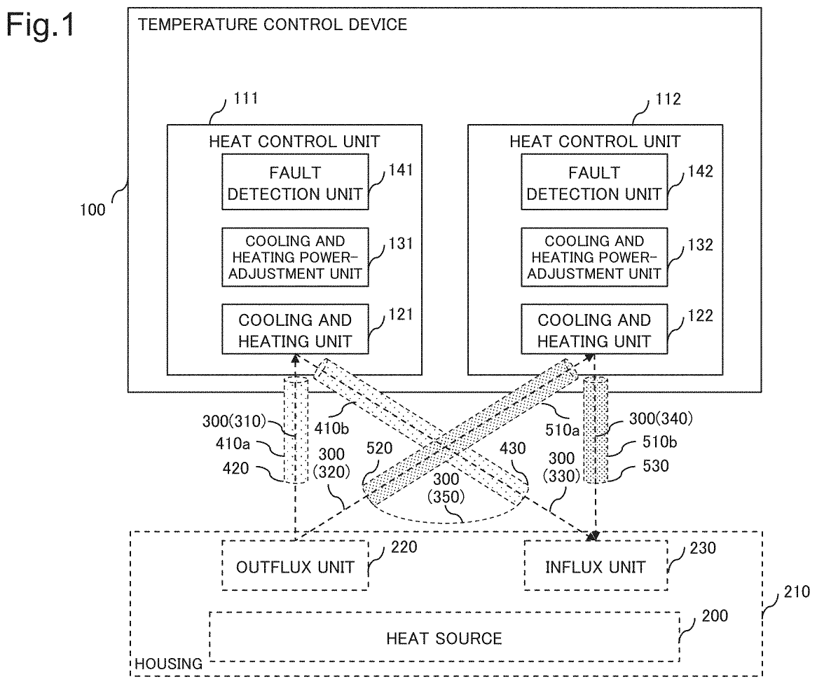

FIG. 1 is a block diagram illustrating one example of a configuration of a temperature control device according to a first example embodiment of the present invention.

Temperature control device 100 according to the present example embodiment controls a temperature of (cools or heats) heat source 200.

Temperature control device 100 is, for example, a local air conditioning machine used for cooling a server being a heat source in a data center. Temperature control device 100 includes heat control unit 111 and heat control unit 112. Note that temperature control device 100 may include three or more heat control units.

Heat control unit 111 includes cooling and heating unit 121, cooling and heating power-adjustment unit 131, and fault detection unit 141.

Cooling and heating unit 121 performs either one of cooling or heating of heat carrier 300. Herein, cooling and heating unit 121 operates by using heat of vaporization or heat of condensation of a heat medium (refrigerant or hot medium), a Peltier effect, or electric heat, for example.

Heat source 200 is a hot heat source or a cold heat source. Heat source 200 is, for example, a server, an electric generator, an internal combustion engine, warm air, cold air, hot water, or cold water.

Heat carrier 300 moves heat between heat source 200 and cooling and heating units 121 and 122. Heat carrier 300 is, for example, a refrigerant or a hot medium being a fluid (liquid or gas) or a heat conductor (such as a metal, a heat pipe, or a fluid that is not to be moved).

When heat carrier 300 is a fluid, heat source 200 may be installed inside housing 210. Herein, housing 210 includes outflux unit 220 from which heat carrier 300 flows out and influx unit 230 into which heat carrier 300 flows.

Cooling and heating power-adjustment unit 131 adjusts a first cooling and heating power being an amount of heat per time to be exchanged in cooling and heating unit 121. Cooling and heating power-adjustment unit 131 adjusts a cooling and heating power by, for example, adjusting a flow rate of a refrigerant or a hot medium (hereinafter simply referred to as a “heat medium”) that operates a heat exchanger. Alternatively, cooling and heating power-adjustment unit 131 adjusts a cooling and heating power by, for example, adjusting a temperature of the heat medium. Cooling and heating power-adjustment unit 131 is, for example, a valve that adjusts a flow rate of the heat medium.

Fault detection unit 141 detects a fault in heat control unit 111. Fault detection unit 141 detects a fault in, for example, cooling and heating unit 121. Fault detection unit 141 detects a fault in cooling and heating unit 121 by measuring a flow rate of, or a temperature difference before and after passage of heat carrier 300 (air when temperature control device 100 is an air conditioning machine, for example) being a heat medium or a fluid that passes through cooling and heating unit 121, for example. In other words, fault detection unit 141 determines that a fault occurs when a flow rate of, or a temperature difference before and after passage of heat carrier 300 being a heat medium or a fluid is smaller than a predetermined threshold value. Fault detection unit 141 is, for example, a temperature sensor or a flow rate sensor.

Heat control unit 112 includes cooling and heating unit 122, cooling and heating power-adjustment unit 132, and fault detection unit 142.

When cooling and heating unit 121 performs cooling of heat carrier 300, cooling and heating unit 122 performs cooling of heat carrier 300. Alternatively, when cooling and heating unit 121 performs heating of heat carrier 300, cooling and heating unit 122 performs heating of heat carrier 300. The remaining configuration in cooling and heating unit 122 is the same as the configuration in cooling and heating unit 121.

Cooling and heating power-adjustment unit 132 adjusts a second cooling and heating power being an amount of heat per time to be exchanged in cooling and heating unit 122. The remaining configuration in cooling and heating power-adjustment unit 132 is the same as the configuration in cooling and heating power-adjustment unit 131.

Fault detection unit 142 detects a fault in heat control unit 112. The remaining configuration in fault detection unit 142 is the same as the configuration in fault detection unit 141.

It is assumed that each of cooling and heating units 121 and 122 has a cooling and heating power (maximum capacity) that can compensate for a decrease in a cooling and heating power in each of the other cooling and heating units 122 and 121 by a rise in a cooling and heating power in each of cooling and heating units 121 and 122, respectively. For example, each of cooling and heating units 121 and 122 has maximum capacity Pₘₐₓ greater than or equal to cooling and heating power Pₜₒₜₐₗ that can perform cooling or heating of heat source 200 with one unit. Then, each of cooling and heating units 121 and 122 can operate in a half of cooling and heating power Pₜₒₜₐₗ in a normal condition. Each of cooling and heating units 121 and 122 can operate alone in cooling and heating power Pₜₒₜₐₗ in a fault condition of the other cooling and heating unit. Alternatively, for example, when temperature control device 100 includes N (N is a natural number of three or more) cooling and heating units, each of the cooling and heating units has maximum capacity Pₘₐₓ being one-(N−1)th of P_{total,} and can operate in one-Nth of cooling and heating power Pₜₒₜₐₗ in a normal condition. Then, each of the cooling and heating units can operate in one-(N−1)th of cooling and heating power Pₜₒₜₐₗ in a fault condition of the other one cooling and heating unit. Alternatively, for example, when each of the cooling and heating units has maximum capacity Pₘₐₓ being one-(N−K)th (K is a natural number of greater than or equal to 2 and less than N) of Pₜₒₜₐₗ, and can operate in one-Nth of cooling and heating power Pₜₒₜₐₗ in a normal condition. Then, each of the cooling and heating units can operate in one-(N−K)th of cooling and heating power Pₜₒₜₐₗ in a fault condition of the other K cooling and heating units.

When heat carrier 300 is a fluid and heat source 200 is installed inside housing 210, cooling and heating units 121 and 122 may be installed in ducts 410 and 510, respectively. For simplifying the diagram, FIG. 1 illustrates one duct 410 being divided up into duct 410a and duct 410b , and illustrates one duct 510 being divided up into duct 510a and duct 510b . Each of ducts 410 and 510 is a structure that limits a movement direction of heat carrier 300 being a fluid. Each of ducts 410 and 510 is, for example, a groove or a pipe having a wall surface perpendicular to a direction that limits the movement of the fluid. Heat carrier 300 flowing out from outflux unit 220, flows in from intake port 420 of duct 410, passes through cooling and heating unit 121, is guided toward influx unit 230, and flows out from outtake port 430. Heat carrier 300 flowing out from outflux unit 220, passes through cooling and heating unit 122, is guided toward influx unit 230, and flows out from outtake port 530.

When duct 410 and duct 510 are present, ducts 410 and 510 may be installed in parallel to each other with respect to influx unit 230 and outflux unit 220. Herein, it is assumed that a plurality of ducts being parallel to each other with respect to influx unit 230 and outflux unit 220 represents that heat carrier 300 flowing out from outflux unit 220 flows out from an outtake port of a certain duct, and then does not flow in from an intake port of another duct before flowing into influx unit 230 in a main flow of heat carrier 300. In other words, by ducts 410 and 510, heat carrier 300 flowing out from outflux unit 220 may flows in from intake ports 420 and 520, and flows out from outtake ports 430 and 530 into influx unit 230 without passing through the other ducts 510 and 410 (paths 310 and 330 and paths 320 and 340), respectively.

Alternatively, when duct 410 and duct 510 are present, duct 410 and duct 510 may be installed in series to each other with respect to influx unit 230 and outflux unit 220. Herein, it is assumed that a plurality of ducts being in series to each other with respect to influx unit 230 and outflux unit 220 represents that heat carrier 300 flowing out from outflux unit 220 successively passes through all the ducts, and then flows into influx unit 230 in a main flow of heat carrier 300. In other words, by duct 510, heat carrier 300 flowing out from outtake port 430 of duct 410 flows in from intake port 520, before flowing into influx unit 230, is guided toward influx unit 230, and flows out from outtake port 530 into influx unit 230 (paths 310, 350, and 340).

Even when ducts 410 and 510 are installed in parallel or in series to each other with respect to influx unit 230 and outflux unit 220, each of cooling and heating units 121 and 122 can contribute to control of a temperature of heat source 200.

An operation in the present example embodiment is described.

First, a main flow of heat carrier 300 and heat when heat carrier 300 is a fluid is described. Heat carrier 300 absorbs heat generated in heat source 201. Then, cooling unit 121 cools a part of heat carrier 300 that has absorbed the heat. Further, cooling unit 122 cools a different part of heat carrier 300 that has absorbed the heat. Then, cooled heat carrier 300 reabsorbs heat generated in heat source 200.

Next, a main flow of heat when heat carrier 300 is a heat conductor is described. Heat carrier 300 absorbs heat generated in heat source 201. Then, cooling unit 121 cools a part of the heat in heat carrier 300 that has absorbed the heat. Further, cooling unit 122 cools a different part of the heat in heat carrier 300 that has absorbed the heat. Then, cooled heat carrier 300 reabsorbs heat generated in heat source 200.

Each of fault detection units 141 and 142 can detect a fault in heat control units 111 and 112, respectively.

Each of cooling and heating power-adjustment units 131 and 132 can adjust the first cooling and heating power and the second cooling and heating power in cooling and heating units 121 and 122, respectively.

Each of cooling and heating units 121 and 122 has a cooling and heating power (maximum capacity) that can compensate for a decrease in a cooling and heating power of each of the other cooling and heating units 122 and 121 by a rise in a cooling and heating power of each of cooling and heating units 121 and 122, respectively. In other words, cooling and heating unit 121 can compensate for a decrease in the second cooling and heating power by a rise in the first cooling and heating power when cooling and heating unit 122 is faulty. Further, cooling and heating unit 122 can compensate for a decrease in the first cooling and heating power by a rise in the second cooling and heating power when cooling and heating unit 121 is faulty.

In other words, in temperature control device 100, when a fault in heat control unit 111 is detected by fault detection unit 141, the second cooling and heating power in cooling and heating unit 122 can be increased by cooling and heating power-adjustment unit 132. Further, when a fault in heat control unit 112 is detected by fault detection unit 142, the first cooling and heating power in cooling and heating unit 121 can be increased by cooling and heating power-adjustment unit 131.

As described above, in temperature control device 100 according to the present example embodiment, a decrease in the first cooling and heating power caused by a fault in heat control unit 111 can be compensated for by an increase in the second cooling and heating power in cooling and heating unit 122. Further, a decrease in the second cooling and heating power caused by a fault in heat control unit 112 can be compensated for by an increase in the first cooling and heating power in cooling and heating unit 121. Therefore, temperature control device 100 according to the present example embodiment has an effect capable of improving fault tolerance in temperature control device 100.

### Second Example Embodiment

Next, a second example embodiment of the present invention based on the first example embodiment of the present invention is described. A temperature control device according to the present example embodiment is a local air conditioning machine. Then, two ducts are installed in parallel to each other.

A configuration according to the present example embodiment is described.

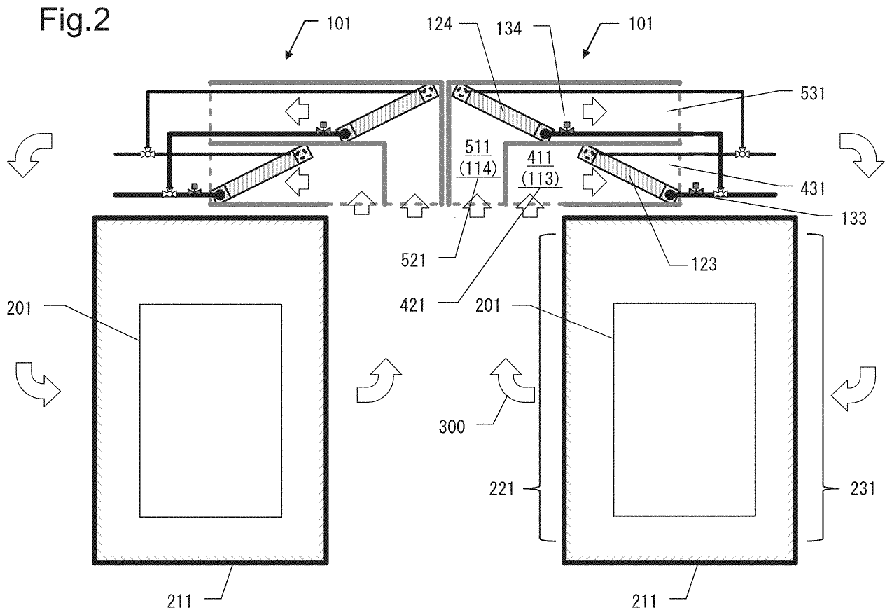

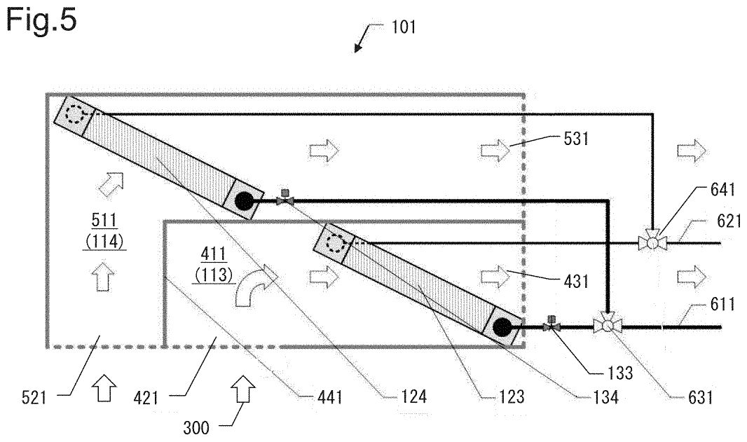

FIGS. 2, 3, 4, and 5 are a front view, a perspective view, a perspective view, and a cross-sectional view of the temperature control device illustrating one example of a configuration of the temperature control device according to the second example embodiment of the present invention, respectively. However, a side surface of the ducts is omitted in FIGS. 2, 3, and 4. Further, FIG. 2 illustrates a pair of temperature control devices 101 and a pair of heat sources 201, but this exemplifies typical arrangement when a cold aisle and a hot aisle are separated in a data center. Even one of temperature control devices 101 and heat sources 201 can operate, and thus one of temperature control devices 101 and heat sources 201 is described hereinafter.

Temperature control device 101 according to the present example embodiment controls a temperature of (cools) heat source 201. Temperature control device 101 is a local air conditioning machine used for cooling a server being heat source 201 in the data center. Temperature control device 101 includes heat control unit 113 and heat control unit 114.

Heat control unit 113 includes cooling unit 123, cooling power adjustment unit 133, fault detection unit 141 (not illustrated), and duct 411.

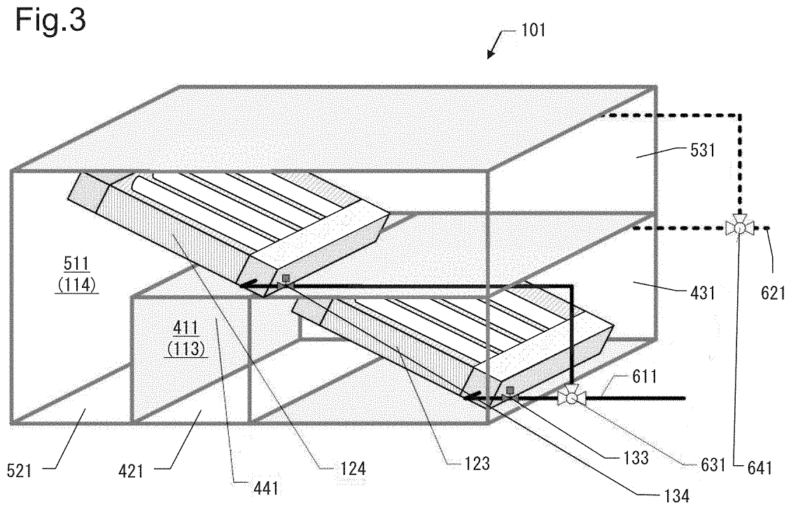

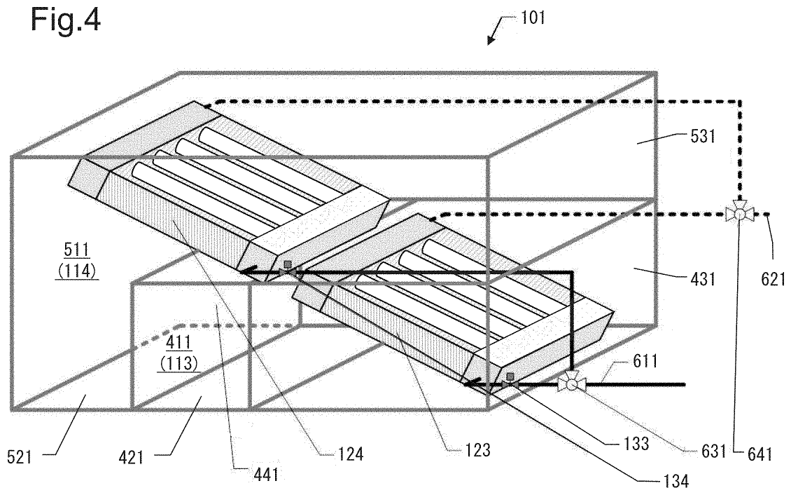

Cooling unit 123 performs cooling of heat carrier 300. Herein, cooling unit 123 is an evaporator that operates by using heat of vaporization of a heat medium (refrigerant). Cooling unit 123 is connected to a heat exhaust device (not illustrated) with piping 611 that transports a heat medium. The heat exhaust device includes a condenser that operates by using heat of condensation of a heat medium. The heat exhaust device discharges heat absorbed by cooling unit 123 to the outside. Cooling unit 123 has a structure in which heat carrier 300 can pass through the inside of an outer shape of cooling unit 123. Cooling unit 123 has a shape (FIGS. 3 and 4) in which a plurality of pipes in which a heat medium flows are provided at intervals between the pipes and are assembled in a plate shape, for example.

Heat source 201 is a hot heat source such as a server installed inside housing 211.

Housing 211 is a server rack that includes outflux unit 221 from which heat carrier 300 flows out and influx unit 231 into which heat carrier 300 flows.

Heat carrier 300 is air that moves heat from heat source 201 to cooling and heating units 123 and 124. However, an outlined thick arrow indicates a flow of heat carrier 300 in FIG. 2 and subsequent drawings.

Cooling power adjustment unit 133 adjusts a first cooling power being an amount of heat per time to be exchanged in cooling unit 123. Cooling power adjustment unit 133 is a valve that adjusts a cooling power by adjusting a flow rate of a heat medium. Alternatively, cooling power adjustment unit 133 may be a valve that adjusts a cooling power by adjusting a temperature of a heat medium (that adjusts a mixing ratio when heat media of two systems having temperatures different from each other are mixed and sent to cooling unit 123).

Fault detection unit 141 detects a fault in cooling unit 123. Fault detection unit 141 detects a fault in cooling unit 123 by measuring a flow rate of, or a temperature difference before and after passage of heat carrier 300 being a heat medium or a fluid that passes through cooling unit 123. Fault detection unit 141 is a temperature sensor or a flow rate sensor. In a case where fault detection unit 141 is a temperature sensor, fault detection unit 141 determines that a fault occurs when a temperature difference of heat carrier 300 being a heat medium or a fluid before and after passing through cooling unit 123 is smaller than a predetermined threshold value (for example, zero). Further, in a case where fault detection unit 141 is a flow rate sensor, fault detection unit 141 determines that a fault occurs when a flow rate of heat carrier 300 being a heat medium or a fluid passing through cooling unit 123 is smaller than a predetermined threshold value (for example, zero). The detected fault may be notified by sound, light, and the like.

Duct 411 is a structure that limits a movement direction of heat carrier 300 being a fluid. Duct 411 transports heat carrier 300 between heat source 201 and cooling unit 123. Duct 411 includes intake port 421 and outtake port 431. Cooling unit 123 is installed inside duct 411. By duct 411, heat carrier 300 flowing out from outflux unit 221 flows in from intake port 421, is guided toward influx unit 231, and flows out from outtake port 431.

Heat control unit 114 includes cooling unit 124, cooling power adjustment unit 134, fault detection unit 142 (not illustrated), and duct 511. Cooling unit 124, cooling power adjustment unit 134, fault detection unit 142, and duct 511 have configurations similar to those of cooling unit 123, cooling power adjustment unit 133, fault detection unit 141, and duct 411, respectively.

Each of cooling units 123 and 124 has maximum capacity Pₘₐₓ greater than or equal to cooling power Pₜₒₜₐₗ that can perform cooling of heat source 201 with one unit.

Ducts 411 and 511 are installed in parallel to each other with respect to influx unit 231 and outflux unit 221. In other words, by ducts 411 and 511, heat carrier 300 flowing out from outflux unit 221 flows in from intake ports 421 and 521, and flows out from outtake ports 431 and 531 into influx unit 231 without passing through the other ducts 511 and 411, respectively.

Ducts 411 and 511 are installed in parallel to each other above housing 211, for example. Further, for example, cooling units 123 and 124 are installed inside ducts 411 and 511 in such a way as to face in a direction inclined to a longitudinal direction of ducts 411 and 511, respectively. Further, for example, cooling units 123 and 124 are installed in parallel to each other.

The remaining configuration according to the present example embodiment is the same as the configuration according to the first example embodiment.

An operation according to the present example embodiment is described.

A main flow of heat carrier 300, a heat medium, and heat is described. Heat carrier 300 inside housing 211 absorbs heat generated in heat source 201. Then, heat carrier 300 that has absorbed the heat flows out from outflux unit 221 to the outside of housing 211, and forms an ascending air current. Then, heat carrier 300 flowing out to the outside of housing 211 ascends to intake port 421, flows into duct 411 from intake port 421, and is then transported to cooling unit 123, or flows into duct 511 from intake port 521 and is then transported to cooling unit 124. Then, when cooling unit 123 is not faulty, cooling unit 123 cools heat carrier 300 transported to cooling unit 123. Further, when cooling unit 124 is not faulty, cooling unit 124 cools heat carrier 300 transported to cooling unit 124. Then, cooled heat carrier 300 forms a descending air current by being discharged from outtake port 431 of duct 411, or being discharged from outtake port 531 of duct 511. Then, discharged heat carrier 300 descends to influx unit 231, and flows from influx unit 231 into housing 211. Then, heat carrier 300 flowing in is returned to heat source 201, and reabsorbs heat generated in heat source 201. Further, the heat absorbed in cooling units 123 and 124 is transported to a heat exhaust device by a refrigerant. Then, the heat exhaust device cools the transported refrigerant. Then, the cooled refrigerant is returned to cooling units 123 and 124, and reabsorbs the heat in cooling units 123 and 124.

Each of cooling units 123 and 124 operates in a half of cooling power Pₜₒₜₐₗ in a normal condition. When the other cooling unit is faulty, each of cooling units 123 and 124 operates alone in cooling power Pₜₒₜₐₗ. Hereinafter, it is assumed that the heat exhaust device constantly transports a heat medium at a constant flow rate, and adjusts presence or absence of distribution of the heat medium to the cooling unit provided with a valve (cooling power adjustment unit). Hereinafter, it is assumed that a valve that controls presence or absence of a flow rate is referred to as a “stop valve”. A valve that communicates with a faulty cooling unit is closed in a fault condition. Then, all the heat medium at a constant flow rate flows into a normal cooling unit, and thus the normal cooling unit operates in cooling power Pᵣₒᵣₐₗ. Note that each valve (cooling power adjustment unit) may determine a flow rate of the heat medium flowing into a certain cooling unit, and the heat exhaust device may transport the whole flow rate of the heat medium flowing into all cooling units. In this case, in a fault condition, a valve that communicates with a faulty cooling unit is closed, and a valve that communicates with a normal cooling unit opens in such a way that a flow rate is double. Then, the heat medium flows twice as much as that in a normal condition into the normal cooling unit, and the normal cooling unit operates in cooling power Pₜₒₜₐₗ.

The remaining operation according to the present example embodiment is the same as the operation according to the first example embodiment.

As described above, in temperature control device 101 according to the present example embodiment, a decrease in the first cooling power caused by a fault in heat control unit 113 can be compensated for by an increase in a second cooling power in cooling unit 124. Further, a decrease in the second cooling power caused by a fault in heat control unit 114 can be compensated for by an increase in the first cooling power in cooling unit 123. Therefore, temperature control device 101 according to the present example embodiment has an effect capable of improving fault tolerance in temperature control device 101.

Further, when ducts 411 and 511 are installed in parallel to each other above housing 211, a size of a space occupied by two ducts 411 and 511 can be suppressed as compared to a case where two ducts 411 and 511 are installed in non-parallel to each other. Therefore, in this case, an effect capable of effectively using a space above housing 211 can be achieved.

### First Modification Example

A first modification example according to the present example embodiment is described.

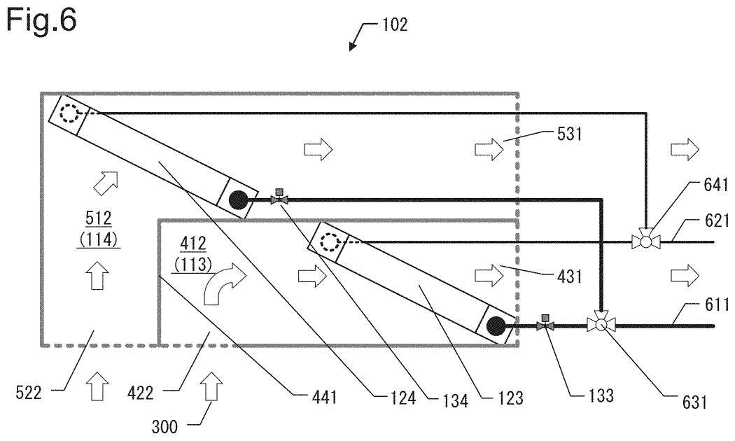

FIG. 6 is a cross-sectional view of the temperature control device illustrating one example of a configuration of the first modification example in the temperature control device according to the second example embodiment of the present invention. However, FIG. 6 illustrates portions of a cooling unit and a duct of the temperature control device according to the present modification example.

In temperature control device 102 according to the present modification example, a path length in duct 412 is shorter than a path length in duct 512. A pressure loss in a duct is generally proportional to a length of the duct and inversely proportional to a cross-sectional area of the duct. Thus, an area of intake port 422 of duct 412 is set to be smaller than an area of intake port 522 of duct 512 by an amount in such a way that a pressure loss in duct 412 is the same as a pressure loss in duct 512. For example, a size of an opening of intake port 422 is set to be smaller than a size of an opening in intake port 522.

In other words, in temperature control device 102, a pressure loss in duct 412 is the same as a pressure loss in duct 512. In other words, in temperature control device 102, a flow rate of heat carrier 300 is the same in cooling unit 123 and cooling unit 124. Therefore, an effect in which imbalance does not occur in an effective value of cooling power in cooling unit 123 and cooling unit 124 can be achieved according to the present modification example.

### Second Modification Example

A second modification example according to the present example embodiment is described.

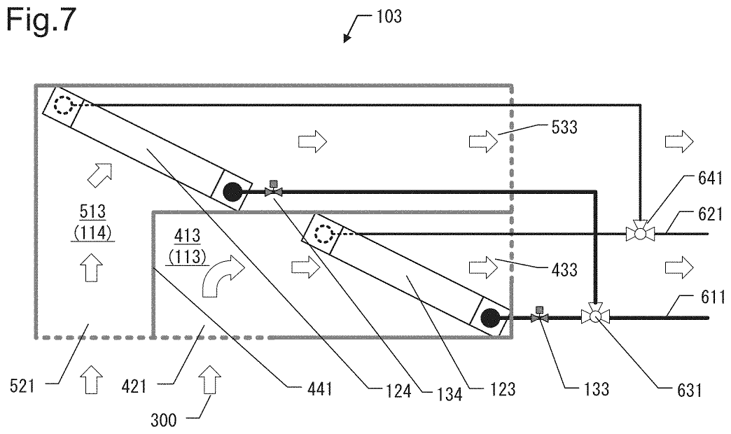

FIG. 7 is a cross-sectional view of the temperature control device illustrating one example of a configuration of the second modification example in the temperature control device according to the second example embodiment of the present invention. However, FIG. 7 illustrates portions of a cooling unit and a duct of the temperature control device according to the present modification example.

In temperature control device 103 according to the present modification example, a path length in duct 413 is shorter than a path length in duct 513. A pressure loss in a duct is generally proportional to a length of the duct and inversely proportional to a cross-sectional area of the duct. Thus, an area of outtake port 433 of duct 413 is set to be smaller than an area of outtake port 533 of duct 513 by an amount in such a way that a pressure loss in duct 413 is the same as a pressure loss in duct 513. For example, a size of an opening of outtake port 433 is set to be smaller than a size of an opening in outtake port 533.

In other words, in temperature control device 103, a pressure loss in duct 413 is the same as a pressure loss in duct 513. In other words, in temperature control device 103, a flow rate of heat carrier 300 is the same in cooling unit 123 and cooling unit 124. Therefore, an effect in which imbalance does not occur in an effective value of cooling power in cooling unit 123 and cooling unit 124 can be achieved according to the present modification example.

Note that a pressure loss may be set to be the same in duct 413 and duct 513 by setting areas of both of intake port 421 and outtake port 433 of duct 413 to be small.

### Third Modification Example

A third modification example according to the present example embodiment is described.

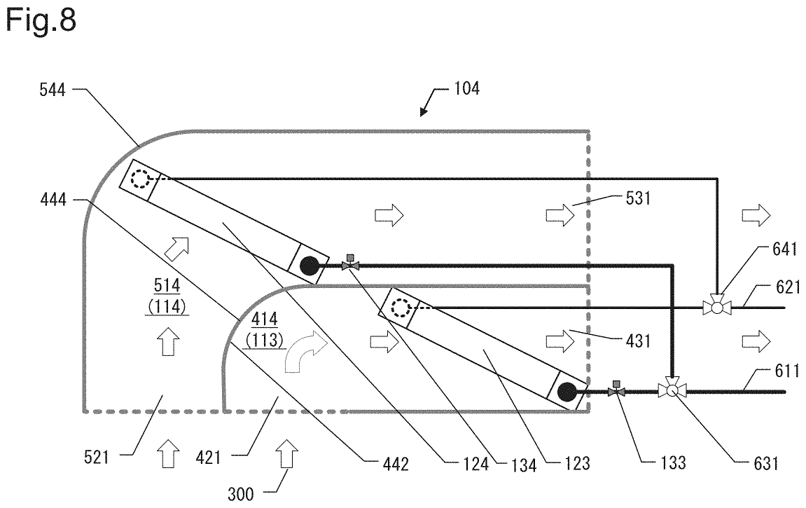

FIG. 8 is a cross-sectional view of the temperature control device illustrating one example of a configuration of the third modification example in the temperature control device according to the second example embodiment of the present invention. However, FIG. 8 illustrates portions of a cooling unit and a duct of the temperature control device according to the present modification example.

In temperature control device 104 according to the present modification example, duct 414 includes curved portion 444 having a corner formed by a curved line. Further, duct 514 includes curved portion 544 having a corner formed by a curved line.

A pressure loss when a direction of a path smoothly changes is generally smaller than a pressure loss when a direction of a path abruptly changes. In other words, in temperature control device 104, a pressure loss in ducts 414 and 514 is smaller than that when a curved portion (having a corner formed by a straight line) that abruptly changes a direction of a path is provided. Therefore, an effect in which a pressure loss is further smaller than that when a corner of a curved portion of a duct is formed by a straight line can be achieved according to the present modification example.

Note that a pressure loss may be set to be further smaller, and the pressure loss may also be set to be the same in duct 414 and duct 514 by setting a corner of duct 414 and duct 514 to be a curved line, and setting areas of at least one of intake port 421 and outtake port 431 of duct 414 to be small as in the first or second modification example.

### Third Example Embodiment

Next, a third example embodiment of the present invention based on the second example embodiment of the present invention is described. In a temperature control device according to the present example embodiment, even one heat control unit can operate, and a second heat control unit can be added.

A configuration according to the present example embodiment is described.

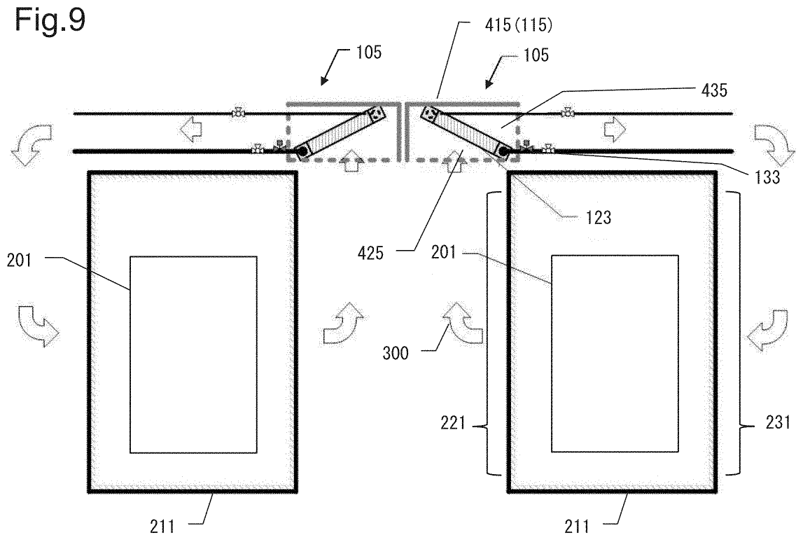

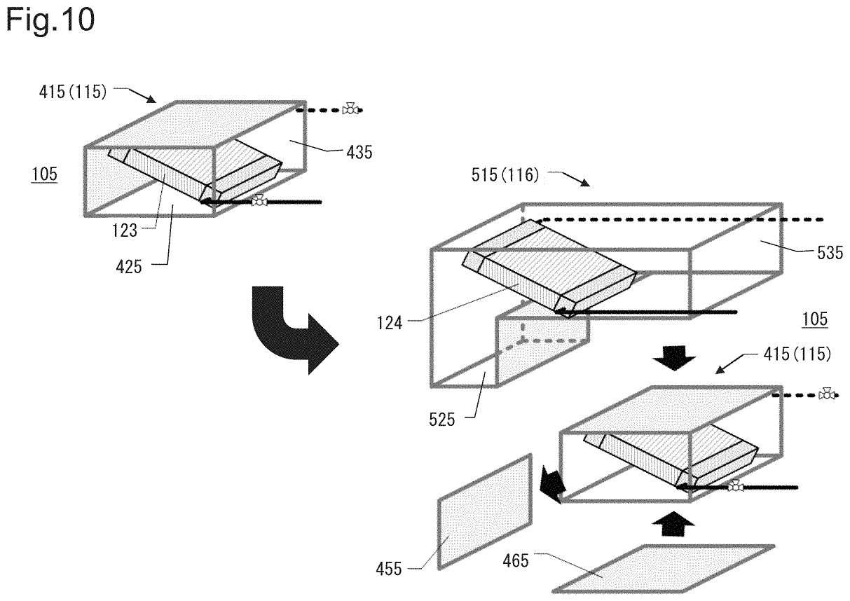

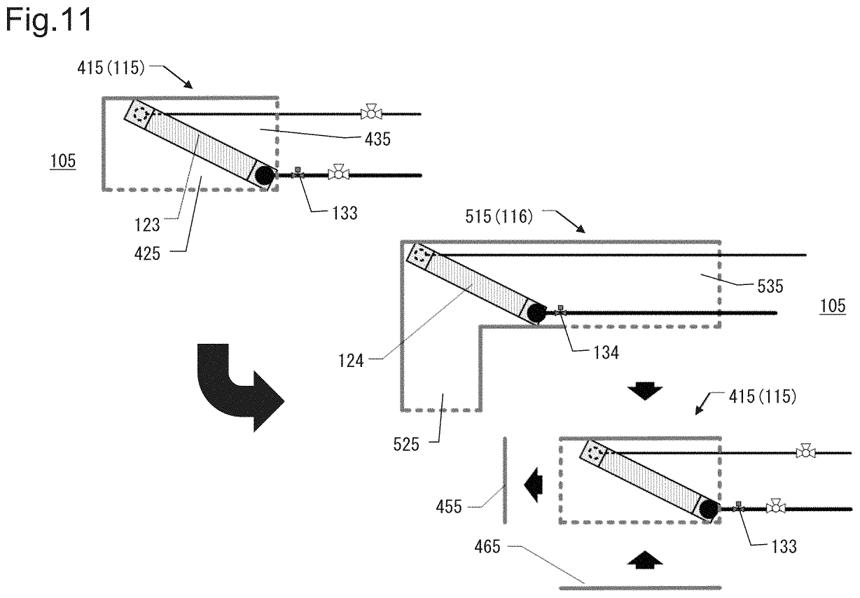

FIGS. 9, 10, and 11 are assembly views of the temperature control device illustrating one example of a configuration of the temperature control device according to the third example embodiment of the present invention. More specifically, FIG. 9 is a cross-sectional view of the temperature control device illustrating one example of the configuration of the temperature control device that operates with one heat control unit. Further, FIGS. 10 and 11 are a perspective view and a cross-sectional view of the temperature control device illustrating a procedure of adding a second heat control unit, respectively. However, a side surface of a duct is omitted in FIGS. 9 and 10.

Temperature control device 105 according to the present example embodiment includes heat control unit 115, and heat control unit 116 can be added.

Heat control unit 115 includes cooling unit 123, cooling power adjustment unit 133, fault detection unit 141 (not illustrated), and duct 415.

Heat control unit 116 includes cooling unit 124, cooling power adjustment unit 134, fault detection unit 142 (not illustrated), and duct 515.

Heat control unit 115 alone can be installed to housing 211 without heat control unit 116 being installed. In duct 415 of heat control unit 115, for example, intake port 425 is open in a lower bottom surface, and outtake port 435 is open in a side surface on a front surface side of housing 211.

Heat control unit 116 can be added to housing 211 after heat control unit 115 is installed. For example, as illustrated in FIG. 10, duct 515 of heat control unit 116 has an L shape bent at 90 degrees on the way. Then, intake port 525 is open in a lower bottom surface of duct 515 on a rear surface side of housing 211, and outtake port 535 is open in a side surface of duct 515 on the front surface side of housing 211. Then, duct 515 can be stacked and installed on duct 415. Further, a size of an opening of intake port 425 can be reduced by plate 465. Further, plate 455 constituting a side surface of duct 415 on the rear surface side of housing 211 can be removed.

The remaining configuration according to the present example embodiment is the same as the configuration according to the second example embodiment.

An operation according to the present example embodiment is described.

First, heat control unit 115 alone is installed to housing 211. Thus, all heat carrier 300 passes through heat control unit 115. Note that heat carrier 300 herein is air that moves heat from a heat source to cooling unit 123. Heat control unit 115 has cooling power Pₜₒₜₐₗ that can perform cooling of the heat source alone. A cooling power of cooling unit 123 is maintained at Pₜₒₜₐₗ by cooling power adjustment unit 133. According to the present example embodiment, cooling power adjustment unit 133 is a stop valve, and thus the cooling power is maintained at Pₜₒₜₐₗ with the valve open.

Next, heat control unit 116 is stacked and installed on duct 415 as illustrated in FIG. 11. At this time, plate 465 is installed on duct 415. Further, plate 455 is removed from duct 415.

Heat carrier 300 branches into cooling units 123 and 124 in a normal condition, and thus each of cooling units 123 and 124 operates in a half of cooling power Pₜₒₜₐₗ. When either cooling units 123 or 124 is faulty, the valve (the cooling power adjustment unit) of the faulty cooling unit is closed. In this way, all heat carrier 300 flows into the normal cooling unit, and thus the normal cooling unit operates in cooling power Pₜₒₜₐₗ.

The remaining operation according to the present example embodiment is the same as the operation according to the second example embodiment.

As described above, in temperature control device 105 according to the present example embodiment, heat control unit 115 alone can be installed to housing 211 without heat control unit 116 being installed. Then, heat control unit 116 can be added to housing 211 after heat control unit 115 is installed. Therefore, temperature control device 105 according to the present example embodiment has an effect capable of improving fault tolerance in temperature control device 105 later as necessary in addition to the effect according to the second example embodiment of the present invention.

### Fourth Example Embodiment

Next, a fourth example embodiment of the present invention based on the third example embodiment of the present invention is described. In a temperature control device according to the present example embodiment, one heat control unit is installed on a rear surface of a housing. However, two ducts are installed in series to each other.

A configuration according to the present example embodiment is described.

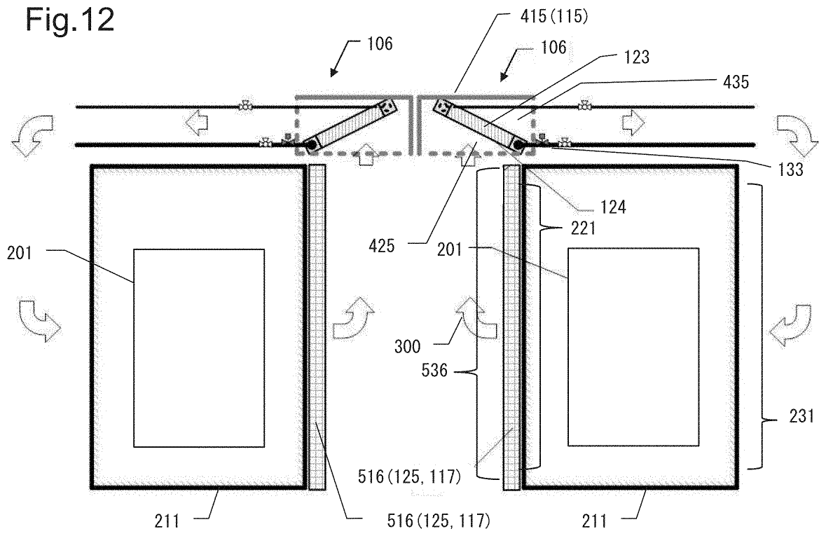

FIG. 12 is a cross-sectional view of the temperature control device illustrating one example of a configuration of the temperature control device according to the fourth example embodiment of the present invention. However, a side surface of a duct is omitted in FIG. 12.

Temperature control device 106 according to the present example embodiment includes heat control unit 115 and heat control unit 117.

Heat control unit 117 includes cooling unit 125, a cooling power adjustment unit (not illustrated), fault detection unit 142 (not illustrated), and duct 516.

By duct 415, heat carrier 300 flowing out from outtake port 536 of duct 516 flows in from intake port 425 before flowing into influx unit 231, is guided toward influx unit 231, and flows out from outtake port 435.

Influx unit 231 is open in the entire surface of a front surface of housing 211.

Outflux unit 221 is open in the entire surface of a rear surface of housing 211.

Duct 516 has a shape of a quadrangular tube with flat side surfaces, and is installed in parallel to the rear surface of housing 211.

Cooling unit 125 has a shape of a quadrangular prism with a thin plate, and is installed in parallel to the rear surface of housing 211 inside duct 516.

Intake port 425 of duct 415 is installed above outtake port 536 of duct 516.

Outtake port 435 of duct 415 is installed above housing 211 in such a way as to face a front surface side of housing 211.

Cooling unit 123 is installed inside duct 415 in such a way as to face in a direction inclined to a longitudinal direction of duct 415.

The remaining configuration according to the present example embodiment is the same as the configuration according to the third example embodiment.

An operation according to the present example embodiment is described.

Each of cooling units 123 and 125 has cooling and heating power Pₜₒₜₐₗ that can perform cooling of a heat source alone. Each of cooling units 123 and 125 operates in a half of cooling power Pₜₒₜₐₗ in a normal condition. When one of cooling units 123 and 125 is faulty, a normal cooling unit operates alone in cooling power Pₜₒₜₐₗ. In other words, when cooling unit 123 is faulty, heat carrier 300 flows into only normal cooling unit 125 by adjusting cooling power adjustment unit 133, that is, closing a valve of cooling unit 123, and thus cooling unit 125 operates in cooling power Pₜₒₜₐₗ. Further, although it is not illustrated, cooling unit 125 includes a cooling power adjustment unit similar to that of cooling unit 123, and a valve operation similar to that in a fault condition of cooling unit 123 is performed in a fault condition of cooling unit 125.

The remaining operation according to the present example embodiment is the same as the operation according to the third example embodiment.

As described above, in temperature control device 106 according to the present example embodiment, a decrease in a first cooling power caused by a fault in heat control unit 117 can be compensated for by an increase in a second cooling power in cooling unit 124. Further, a decrease in the second cooling power caused by a fault in heat control unit 115 can be compensated for by an increase in the first cooling power in cooling unit 125. Therefore, temperature control device 106 according to the present example embodiment has an effect capable of improving fault tolerance in temperature control device 106.

### Fifth Example Embodiment

Next, a fifth example embodiment of the present invention based on the first example embodiment of the present invention is described. A temperature control device according to the present example embodiment further includes a redundancy control unit that performs redundancy control of a plurality of heat control units.

A configuration according to the present example embodiment is described.

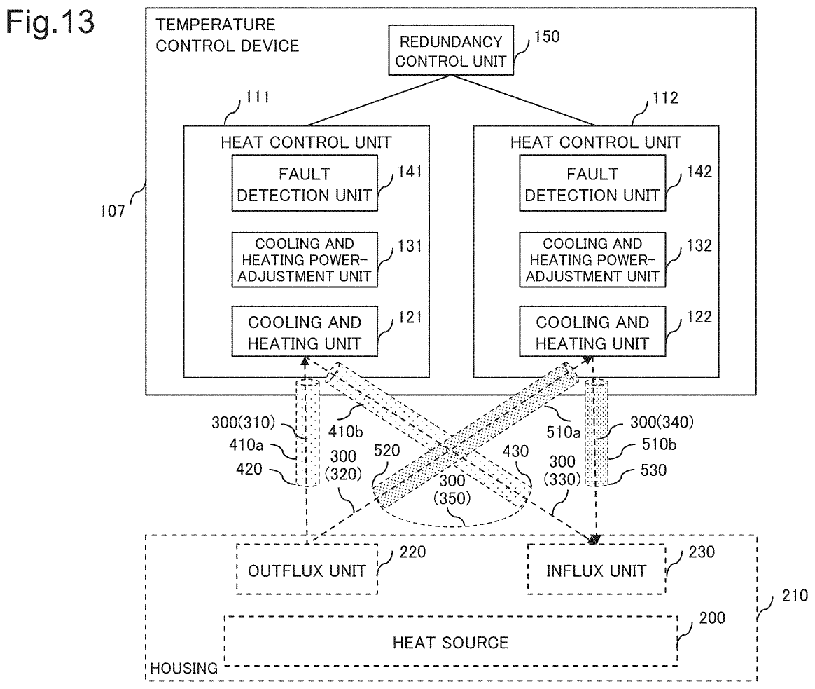

FIG. 13 is a block diagram illustrating one example of a configuration of the temperature control device according to the fifth example embodiment of the present invention.

Temperature control device 107 includes heat control unit 111, heat control unit 112, and redundancy control unit 150.

Redundancy control unit 150 controls a cooling and heating power in cooling and heating unit 121 by cooling and heating power-adjustment unit 131. Further, redundancy control unit 150 controls a cooling and heating power in cooling and heating unit 122 by cooling and heating power-adjustment unit 132.

The remaining configuration according to the present example embodiment is the same as the configuration according to the first example embodiment.

An operation according to the present example embodiment is described.

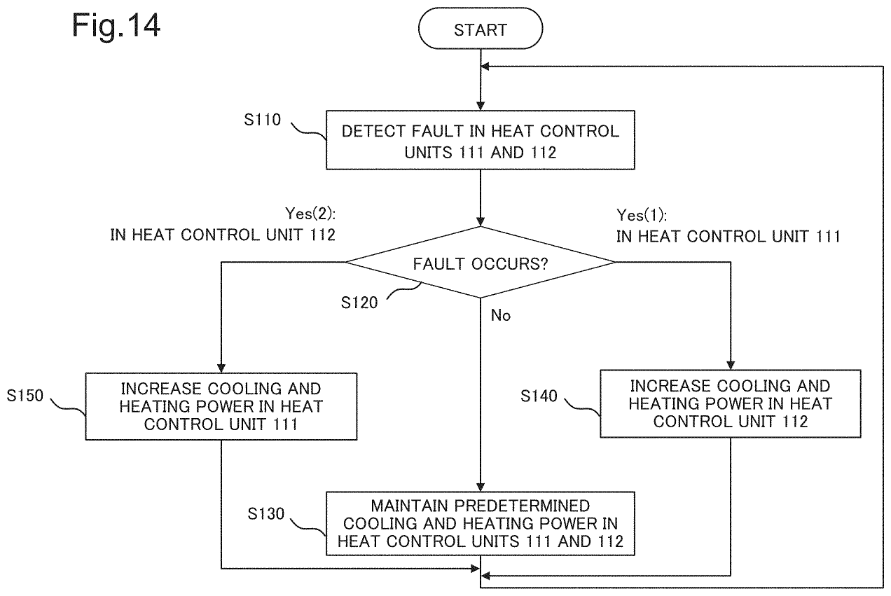

FIG. 14 is a flowchart illustrating an operation of the temperature control device according to the first example embodiment of the present invention. Note that the flowchart illustrated in FIG. 14 and the following description are one example, and a processing order and the like may be changed, processing may return, and processing may be repeated according to processing being appropriately acquired.

First, redundancy control unit 150 detects a fault in heat control unit 111 and heat control unit 112 by fault detection unit 141 and fault detection unit 142 (Step S110).

When a fault is not detected (Step S120: No), redundancy control unit 150 maintains a cooling and heating power in cooling and heating unit 121 and cooling and heating unit 122 at a predetermined power value (for example, a half of Pₜₒₜₐₗ) by cooling and heating power-adjustment unit 131 and cooling and heating power-adjustment unit 132, respectively (Step S130), and the processing returns to Step S110.

When a fault in heat control unit 111 is detected by fault detection unit 141 (Step S120: Yes (1)), redundancy control unit 150 increases the cooling and heating power in cooling and heating unit 122 by cooling and heating power-adjustment unit 132 (Step S140), and the processing returns to Step S110. Herein, for example, redundancy control unit 150 increases the cooling and heating power in cooling and heating unit 122 by a decrease (for example, a half of Pₜₒₜₐₗ) of the cooling and heating power in cooling and heating unit 121.

When a fault in heat control unit 112 is detected by fault detection unit 142 (Step S120: Yes (2)), redundancy control unit 150 increases the cooling and heating power in cooling and heating unit 121 by cooling and heating power-adjustment unit 131 (Step S150), and the processing returns to Step S110. Herein, for example, redundancy control unit 150 increases the cooling and heating power in cooling and heating unit 121 by a decrease (for example, a half of Pₜₒₜₐₗ) of the cooling and heating power in cooling and heating unit 122.

The remaining operation according to the present example embodiment is the same as the operation according to the first example embodiment.

As described above, in temperature control device 107 according to the present example embodiment, when a fault in heat control unit 111 is detected by fault detection unit 141, redundancy control unit 150 increases a second cooling and heating power in cooling and heating unit 122 by cooling and heating power-adjustment unit 132. Further, when a fault in heat control unit 112 is detected by fault detection unit 142, redundancy control unit 150 increases a first cooling and heating power in cooling and heating unit 121 by cooling and heating power-adjustment unit 131. In other words, a decrease in the first cooling and heating power caused by a fault in heat control unit 111 is compensated for by an increase in the second cooling and heating power in cooling and heating unit 122. Further, a decrease in the second cooling and heating power caused by a fault in heat control unit 112 is compensated for by an increase in the first cooling and heating power in cooling and heating unit 121. Therefore, temperature control device 107 according to the present example embodiment has an effect capable of improving fault tolerance in temperature control device 107.

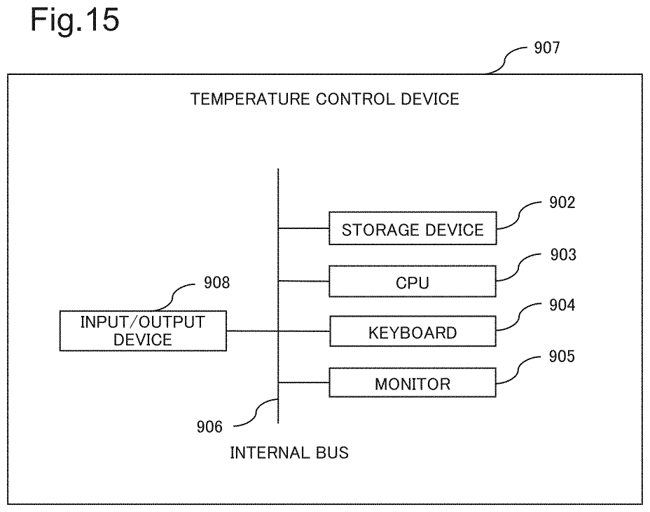

FIG. 15 is a block diagram illustrating one example of a hardware configuration that can achieve the temperature control device according to each of the example embodiments of the present invention.

Temperature control device 907 includes storage device 902, central processing unit (CPU) 903, keyboard 904, monitor 905, and input/output (I/O) device 908, which are connected with internal bus 906. Storage device 902 stores an operation program of CPU 903 such as redundancy control unit 150, fault detection units 141 and 142, and cooling and heating power-adjustment units 131 and 132. CPU 903 controls the whole temperature control device 907, executes the operation program stored in storage device 902, and performs execution of a program of redundancy control unit 150 and the like and transmission and reception of data via input/output device 908. Note that the internal configuration of temperature control device 907 described above is one example. Temperature control device 907 may have a device configuration that connects keyboard 904 and monitor 905 as necessary.

The temperature control device according to each of the example embodiments of the present invention described above may be achieved by a dedicated device, and can also be achieved by a computer (information processing device) other than an operation of hardware that causes input/output device 908 to perform communication with the outside. In this case, the computer reads, in CPU 903, a software program stored in storage device 902, and executes the read software program in CPU 903. In a case of each of the example embodiments described above, description capable of achieving a function of each unit such as redundancy control unit 150, fault detection units 141 and 142, and cooling and heating power-adjustment units 131 and 132 illustrated in FIG. 1 or 13 as described above may be made in the software program. However, it is also assumed that each of the units appropriately includes hardware. Then, in such a case, the software program (the computer program) can be regarded to constitute the present invention. Furthermore, a computer-readable storage medium that stores the software program can also be regarded to constitute the present invention.

The present invention is exemplarily described above by each of the example embodiments and the modification examples thereof described above. However, a technical scope of the present invention is not limited to a scope described in each of the example embodiments and the modification examples thereof described above. It is obvious to a person skilled in the art that various modifications or improvements can be added to the example embodiment. In such a case, a new example embodiment to which the modifications or the improvements are added may also be included in the technical scope of the present invention. Then, this is obvious from a matter described in claims.

The whole or part of the example embodiments disclosed above can be described as, but not limited to, the following supplementary notes.
(Supplementary note 1)

A temperature control device, comprising:

first heat control means including
first cooling and heating means for performing either one of cooling or heating of a heat carrier that moves heat from and to a heat source, and
first cooling and heating power-adjustment means for adjusting a first cooling and heating power being an amount of heat per time to be exchanged in the first cooling and heating means; and

second heat control means that includes
second cooling and heating means for performing either one of cooling of the heat carrier when the first cooling and heating means performs cooling of the heat carrier, or heating of the heat carrier when the first cooling and heating means performs heating of the heat carrier, and
second cooling and heating power-adjustment means for adjusting a second cooling and heating power being an amount of heat per time to be exchanged in the second cooling and heating means, and

that can compensate for a decrease in the first cooling and heating power by a rise in the second cooling and heating power, and can compensate for a decrease in the second cooling and heating power by a rise in the first cooling and heating power.
(Supplementary note 2)

A temperature control device, comprising:

a first duct through which a heat carrier flowing out from an outflux unit of a housing, which includes the outflux unit from which the heat carrier being a fluid flows out and an influx unit into which the heat carrier flows, and in which a heat source is installed, flows in from a first intake port, is guided toward the influx unit, and flows out from a first outtake port, and in which first cooling and heating means is installed; and

a second duct through which the heat carrier flowing out from the outflux unit flows in from a second intake port, is guided toward the influx unit, and flows out from a second outtake port, and in which second cooling and heating means is installed.
(Supplementary note 3)

The temperature control device according to supplementary note 2, wherein

each of the first duct and the second duct is installed in parallel to each other with respect to the outflux unit and the influx unit.
(Supplementary note 4)

The temperature control device according to supplementary note 2 or 3, wherein

the first cooling and heating means is installed inside the first duct in such a way as to face in a direction inclined to a longitudinal direction of the first duct, and

the second cooling and heating means is installed inside the second duct in such a way as to face in a direction inclined to a longitudinal direction of the second duct.
(Supplementary note 5)

The temperature control device according to any one of supplementary notes 2 to 4, wherein

each of the first cooling and heating means and the second cooling and heating means is installed above the housing, and performs cooling of the heat carrier, and

a longitudinal direction of the first duct near a position in which the first cooling and heating means is installed and a longitudinal direction of the second duct near a position in which the second cooling and heating means is installed are parallel to each other.
(Supplementary note 6)

The temperature control device according to any one of supplementary notes 2 to 5, wherein

a first path length in the first duct is shorter than a second path length in the second duct, and

a first area in the first intake port is smaller than a second area in the second intake port by an amount in such a way that a first pressure loss in the first duct is the same as a second pressure loss in the second duct.
(Supplementary note 7)

The temperature control device according to any one of supplementary notes 2 to 6, wherein

a first path length in the first duct is shorter than a second path length in the second duct, and

a third area in the first outtake port is smaller than a fourth area in the second outtake port by an amount in such a way that a first pressure loss in the first duct is the same as a second pressure loss in the second duct.
(Supplementary note 8)

The temperature control device according to any one of supplementary notes 5 to 7, wherein

the first duct includes a first curved portion that smoothly changes a direction of a path, and

the second duct includes a second curved portion that smoothly changes a direction of a path.
(Supplementary note 9)

The temperature control device according to supplementary note 2, wherein

by the second duct, the heat carrier flowing out from the first outtake port of the first duct, flows in from the second intake port, is guided toward the influx unit, and flows out from the second outtake port.
(Supplementary note 10)

The temperature control device according to supplementary note 9, wherein

the influx unit is open in an entire surface of a front surface of the housing,

the outflux unit is open in an entire surface of a rear surface of the housing,

the first duct is installed along a rear surface of the housing,

the first cooling and heating means is installed inside the first duct along a rear surface of the housing,

the second intake port of the second duct is installed above the first outtake port of the first duct,

the second outtake port of the second duct is installed above the housing in such a way as to face a front surface side of the housing, and

the second cooling and heating means is installed inside the second duct in such a way as to face in a direction inclined to a longitudinal direction of the second duct.
(Supplementary note 11)

The temperature control device according to supplementary note 1, wherein

the first heat control means alone can be installed close to a housing without the second heat control means being installed,

when the first heat control means is installed alone, the first cooling and heating power is set to have a value at which heat from the housing can be cooled, and

the second heat control means can be added to the housing after the first heat control means is installed, and heat from the housing can be cooled or heated by combining cooling and heating powers by the first heat control means and the second heat control means after addition.
(Supplementary note 12)

The temperature control device according to supplementary note 1 or 11, comprising redundancy control means, wherein

the first heat control means includes first fault detection means for detecting a fault in the first heat control means,

the second heat control means includes second fault detection means for detecting a fault in the second heat control means,

when a fault in the first heat control means is not detected by the first fault detection means, and a fault in the second heat control means is not detected by the second fault detection means, heat from the heat source can be cooled or heated by combining cooling and heating powers by the first heat control means and the second heat control means,

when a fault in the first heat control means is detected by the first fault detection means, the second cooling and heating power of the second heat control means is set to have a value at which heat from the heat source can be cooled or heated by the second heat control means alone, and

when a fault in the second heat control means is detected by the second fault detection means, the first cooling and heating power of the first heat control means is set to have a value at which heat from the heat source can be cooled by the first heat control means alone.
(Supplementary note 13)

A method of controlling a temperature control device including:

first heat control means including
first cooling and heating means for performing either one of cooling or heating of a heat carrier that moves heat from and to a heat source,
first cooling and heating power-adjustment means for adjusting a first cooling and heating power being an amount of heat per time to be exchanged in the first cooling and heating means, and
first fault detection means for detecting a fault in own heat control means; and
second heat control means including
second cooling and heating means for performing either one of cooling of the heat carrier when the first cooling and heating means performs cooling of the heat carrier, or heating of the heat carrier when the first cooling and heating means performs heating of the heat carrier,
second cooling and heating power-adjustment means for adjusting a second cooling and heating power being an amount of heat per time to be exchanged in the second cooling and heating means, and
second fault detection means for detecting a fault in own heat control means, the method comprising:

when a fault in the first heat control means is not detected by the first fault detection means, and a fault in the second heat control means is not detected by the second fault detection means, setting a value at which heat from the heat source can be cooled by combining the first cooling and heating power in the first cooling and heating means being set by the first cooling and heating power-adjustment means and the second cooling and heating power in the second cooling and heating means being set by the second cooling and heating power-adjustment means;

when a fault in the first heat control means is detected by the first fault detection means, increasing, by the second cooling and heating power-adjustment means, the second cooling and heating power in the second cooling and heating means to a value at which heat from the heat source can be cooled by the second heat control means alone; and

when a fault in the second heat control means is detected by the second fault detection means, increasing, by the first cooling and heating power-adjustment means, the first cooling and heating power in the first cooling and heating means to a value at which heat from the heat source can be cooled by the first heat control means alone.
(Supplementary note 14)

A non-temporary storage medium that stores a control program for a temperature control device including:

first heat control means including
first cooling and heating means for performing either one of cooling or heating of a heat carrier that moves heat from and to a heat source,
first cooling and heating power-adjustment means for adjusting a first cooling and heating power being an amount of heat per time to be exchanged in the first cooling and heating means, and
first fault detection means for detecting a fault in own heat control means; and

second heat control means including
second cooling and heating means for performing either one of cooling of the heat carrier when the first cooling and heating means performs cooling of the heat carrier, or heating of the heat carrier when the first cooling and heating means performs heating of the heat carrier,
second cooling and heating power-adjustment means for adjusting a second cooling and heating power being an amount of heat per time to be exchanged in the second cooling and heating means, and
second fault detection means for detecting a fault in own heat control means,

the control program causing a computer included in the temperature control device to execute redundancy control processing of:

when a fault in the first heat control means is not detected by the first fault detection means, and a fault in the second heat control means is not detected by the second fault detection means, setting a value at which heat from the heat source can be cooled by combining the first cooling and heating power in the first cooling and heating means being set by the first cooling and heating power-adjustment means and the second cooling and heating power in the second cooling and heating means being set by the second cooling and heating power-adjustment means;

when a fault in the first heat control means is detected by the first fault detection means, increasing, by the second cooling and heating power-adjustment means, the second cooling and heating power in the second cooling and heating means to a value at which heat from the heat source can be cooled by the second heat control means alone; and

when a fault in the second heat control means is detected by the second fault detection means, increasing, by the first cooling and heating power-adjustment means, the first cooling and heating power in the first cooling and heating means to a value at which heat from the heat source can be cooled by the first heat control means alone.

### INDUSTRIAL APPLICABILITY

The present invention can be used for improving fault tolerance related to a temperature control function in an air conditioning machine, a cooling machine, a heating machine, a cooler, a heater, a refrigerator, a freezer, an electric generator, an internal combustion engine, a server, and the like.

### REFERENCE SIGNS LIST

100, 101, 102, 103, 104, 105, 106 Temperature control device
111, 112, 113, 114, 115, 116, 117 Heat control unit
121, 122 Cooling and heating unit
123, 124, 125 Cooling unit
131, 132 Cooling and heating power-adjustment unit
133, 134 Cooling power adjustment unit
141, 142 Fault detection unit
150 Redundancy control unit
200, 201 Heat source
210, 211 Housing
220, 221 Outflux unit
230, 231 Influx unit
300 Heat carrier
310, 320, 330, 340, 350 Path
410, 411, 412, 413, 414, 415, 510, 511, 512, 513, 514, 515, 516 Duct
410a , 410b , 510a , 510b Duct
420, 421, 422, 425, 520, 521, 522, 525 Intake port
430, 431, 433, 435, 530, 531, 533, 535, 536 Outtake port
441, 442, 455, 465 Plate
444, 544 Curved portion
611, 621 Piping
631, 641 Branch pipe
902 Storage device
903 CPU
904 Keyboard
905 Monitor
906 Internal bus
907 Temperature control device
908 Input/output device

1. (canceled)

2. A temperature control device, comprising:
a first duct through which a heat carrier flowing out from an outflux unit of a housing, which includes the outflux unit from which the heat carrier being a fluid flows out and an influx unit into which the heat carrier flows, and in which a heat source is installed, flows in from a first intake port, is guided toward the influx unit, and flows out from a first outtake port, and in which a first cooling and heating unit is installed; and
a second duct through which the heat carrier flowing out from the outflux unit flows in from a second intake port, is guided toward the influx unit, and flows out from a second outtake port, and in which a second cooling and heating unit is installed.

3. The temperature control device according to claim 2, wherein
each of the first duct and the second duct is installed in parallel to each other with respect to the outflux unit and the influx unit.

4. The temperature control device according to claim 2, wherein
the first cooling and heating unit is installed inside the first duct in such a way as to face in a direction inclined to a longitudinal direction of the first duct, and
the second cooling and heating unit is installed inside the second duct in such a way as to face in a direction inclined to a longitudinal direction of the second duct.

5. The temperature control device according to claim 2, wherein
each of the first cooling and heating unit and the second cooling and heating unit is installed above the housing, and performs cooling of the heat carrier, and
a longitudinal direction of the first duct near a position in which the first cooling and heating unit is installed and a longitudinal direction of the second duct near a position in which the second cooling and heating unit is installed are parallel to each other.

6. The temperature control device according to claim 2, wherein
a first path length in the first duct is shorter than a second path length in the second duct, and
a first area in the first intake port is smaller than a second area in the second intake port by an amount in such a way that a first pressure loss in the first duct is the same as a second pressure loss in the second duct.

7. The temperature control device according to claim 2, wherein
a first path length in the first duct is shorter than a second path length in the second duct, and
a third area in the first outtake port is smaller than a fourth area in the second outtake port by an amount in such a way that a first pressure loss in the first duct is the same as a second pressure loss in the second duct.

8. The temperature control device according to claim 5, wherein
the first duct includes a first curved portion that smoothly changes a direction of a path, and
the second duct includes a second curved portion that smoothly changes a direction of a path.

9. The temperature control device according to claim 2, wherein
by the second duct, the heat carrier flowing out from the first outtake port of the first duct, flows in from the second intake port, is guided toward the influx unit, and flows out from the second outtake port.

10. The temperature control device according to claim 9, wherein
the influx unit is open in an entire surface of a front surface of the housing,
the outflux unit is open in an entire surface of a rear surface of the housing,
the first duct is installed along a rear surface of the housing,
the first cooling and heating unit is installed inside the first duct along a rear surface of the housing,
the second intake port of the second duct is installed above the first outtake port of the first duct,
the second outtake port of the second duct is installed above the housing in such a way as to face a front surface side of the housing, and
the second cooling and heating unit is installed inside the second duct in such a way as to face in a direction inclined to a longitudinal direction of the second duct.

11. (canceled)

12. (canceled)

13. A method of controlling a temperature control device including:
a first heat control unit including
a first cooling and heating unit configured to perform either one of cooling or heating of a heat carrier that moves heat from and to a heat source,
a first cooling and heating power-adjustment unit configured to adjust a first cooling and heating power being an amount of heat per time to be exchanged in the first cooling and heating unit, and
a first fault detection unit configured to detect a fault in own heat control unit; and
a second heat control unit including
a second cooling and heating unit configured to perform either one of cooling of the heat carrier when the first cooling and heating unit performs cooling of the heat carrier, or heating of the heat carrier when the first cooling and heating unit performs heating of the heat carrier,
a second cooling and heating power-adjustment unit configured to adjust a second cooling and heating power being an amount of heat per time to be exchanged in the second cooling and heating unit, and
a second fault detection unit configured to detect a fault in own heat control unit, the method comprising:
when a fault in the first heat control unit is not detected by the first fault detection unit,and a fault in the second heat control unit is not detected by the second fault detection unit, setting a value at which heat from the heat source can be cooled by combining the first cooling and heating power in the first cooling and heating unit being set by the first cooling and heating power-adjustment unit and the second cooling and heating power in the second cooling and heating unit being set by the second cooling and heating power-adjustment unit;
when a fault in the first heat control unit is detected by the first fault detection unit, increasing, by the second cooling and heating power-adjustment unit, the second cooling and heating power in the second cooling and heating unit to a value at which heat from the heat source can be cooled by the second heat control unit alone; and
when a fault in the second heat control unit is detected by the second fault detection unit, increasing, by the first cooling and heating power-adjustment unit, the first cooling and heating power in the first cooling and heating unit, to a value at which heat from the heat source can be cooled by the first heat control unit alone.

14. A non-temporary storage medium that stores a control program for a temperature control device including:
a first heat control unit including
a first cooling and heating unit configured to perform either one of cooling or heating of a heat carrier that moves heat from and to a heat source,
a first cooling and heating power-adjustment unit configured to adjust a first cooling and heating power being an amount of heat per time to be exchanged in the first cooling and heating unit, and
a first fault detection unit configured to detect a fault in own heat control unit; and
a second heat control unit including
a second cooling and heating unit configured to perform either one of cooling of the heat carrier when the first cooling and heating unit performs cooling of the heat carrier, or heating of the heat carrier when the first cooling and heating unit performs heating of the heat carrier,
a second cooling and heating power-adjustment unit configured to adjust a second cooling and heating power being an amount of heat per time to be exchanged in the second cooling and heating unit, and
a second fault detection unit configured to detect a fault in own heat control unit,
the control program causing a computer included in the temperature control device to execute redundancy control processing of:
when a fault in the first heat control unit is not detected by the first fault detection unit, and a fault in the second heat control unit is not detected by the second fault detection unit, setting a value at which heat from the heat source can be cooled by combining the first cooling and heating power in the first cooling and heating unit being set by the first cooling and heating power-adjustment unit and the second cooling and heating power in the second cooling and heating unit being set by the second cooling and heating power-adjustment unit;
when a fault in the first heat control unit is detected by the first fault detection unit, increasing, by the second cooling and heating power-adjustment unit, the second cooling and heating power in the second cooling and heating unit to a value at which heat from the heat source can be cooled by the second heat control unit alone; and
when a fault in the second heat control unit is detected by the second fault detection unit, increasing, by the first cooling and heating power-adjustment unit, the first cooling and heating power in the first cooling and heating unit to a value at which heat from the heat source can be cooled by the first heat control unit alone.

15. The temperature control device according to claim 3, wherein
the first cooling and heating unit is installed inside the first duct in such a way as to face in a direction inclined to a longitudinal direction of the first duct, and
the second cooling and heating unit is installed inside the second duct in such a way as to face in a direction inclined to a longitudinal direction of the second duct.

16. The temperature control device according to claim 3, wherein
each of the first cooling and heating unit and the second cooling and heating unit is installed above the housing, and performs cooling of the heat carrier, and
a longitudinal direction of the first duct near a position in which the first cooling and heating unit is installed and a longitudinal direction of the second duct near a position in which the second cooling and heating unit is installed are parallel to each other.

17. The temperature control device according to claim 4, wherein
each of the first cooling and heating unit and the second cooling and heating unit is installed above the housing, and performs cooling of the heat carrier, and
a longitudinal direction of the first duct near a position in which the first cooling and heating unit is installed and a longitudinal direction of the second duct near a position in which the second cooling and heating unit is installed are parallel to each other.

18. The temperature control device according to claim 3, wherein
a first path length in the first duct is shorter than a second path length in the second duct, and
a first area in the first intake port is smaller than a second area in the second intake port by an amount in such a way that a first pressure loss in the first duct is the same as a second pressure loss in the second duct.

19. The temperature control device according to claim 4, wherein
a first path length in the first duct is shorter than a second path length in the second duct, and
a first area in the first intake port is smaller than a second area in the second intake port by an amount in such a way that a first pressure loss in the first duct is the same as a second pressure loss in the second duct.

20. The temperature control device according to claim 5, wherein
a first path length in the first duct is shorter than a second path length in the second duct, and
a first area in the first intake port is smaller than a second area in the second intake port by an amount in such a way that a first pressure loss in the first duct is the same as a second pressure loss in the second duct.

21. The temperature control device according to claim 3, wherein
a first path length in the first duct is shorter than a second path length in the second duct, and
a third area in the first outtake port is smaller than a fourth area in the second outtake port by an amount in such a way that a first pressure loss in the first duct is the same as a second pressure loss in the second duct.
